(19) United States
(12) Patent Application Publication
(10) Pub. No.: US 2025/0182825 A1
(43) Pub. Date: Jun. 5, 2025

(54) CONTENT ADDRESSABLE MEMORY DEVICE AND OPERATING METHOD THEREOF

(71) Applicant: SEOUL NATIONAL UNIVERSITY R&DB FOUNDATION, Seoul (KR)

(72) Inventors: Woo Young CHOI, Seoul (KR); Minjeong RYU, Seoul (KR)

(73) Assignee: SEOUL NATIONAL UNIVERSITY R&DB FOUNDATION, Seoul (KR)

(21) Appl. No.: 18/893,127

(22) Filed: Sep. 23, 2024

(30) Foreign Application Priority Data
Nov. 30, 2023 (KR) 10-2023-0170632
Feb. 22, 2024 (KR) 10-2024-0025973

(51) Int. Cl. G11C 15/04; G11C 11/22; H10B 51/30

(52) U.S. Cl. CPC G11C 15/046; G11C 11/223; G11C 11/2297; H10B 51/30

(57) ABSTRACT

Disclosed is a CAM device including a memory cell array, a voltage generator that respectively provides input signals to rows of the memory cell array, a driver circuit that respectively provides search signals to columns of the memory cell array and respectively provides complementary search signals to the columns, and a priority encoder connected to the rows. A first row includes first to M-th memory transistors respectively connected to the columns. The first memory transistor includes a first source terminal receiving the first complementary search signal, a first gate terminal receiving the first input signal, a first drain terminal receiving the first search signal, and a first electrical element. When a codeword corresponding to the first search signal and the first complementary search signal corresponds to a programmed state of the first electrical element, a capacitance value of the first memory transistor is smaller than a threshold value.

### CROSS-REFERENCE TO RELATED APPLICATIONS

This application claims priority under 35 U.S.C. § 119 to Korean Patent Application No. 10-2023-0170632 filed on Nov. 30, 2023, and No. 10-2024-0025973 filed on Feb. 22, 2024, in the Korean Intellectual Property Office, the disclosures of which are incorporated by reference herein in their entireties.

### BACKGROUND

Embodiments of the present disclosure described herein relate to a memory device and a method thereof, and more particularly, relate to a content addressable memory (CAM) device and an operating method thereof.

The present research has been supported by Samsung Future Technology Fostering Program (Project No. SRFC-TA2103-01).

A CAM device does not perform sequential memory operations based on addresses, but compares all data stored in a memory with data to be found in parallel based on content. Accordingly, the CAM device may be used for high-speed and large-capacity data search, which has recently been utilized in the fields of big data and artificial intelligence.

In general, the CAM device requires two or more transistors per memory cell, thereby limiting the miniaturization of the CAM device. Moreover, the CAM device needs to perform non-linear operations to determine an address at which data to be found is stored, thereby increasing circuit complexity and power consumption.

### SUMMARY

Embodiments of the present disclosure provide a CAM device and an operating method thereof.

According to an embodiment, a CAM device communicating with a processor includes a memory cell array including first to N-th rows and first to M-th columns, a voltage generator that respectively provides first to N-th input signals to the first to N-th rows under control of the processor, a driver circuit that respectively provides first to M-th search signals to the first to M-th columns and respectively provides first to M-th complementary search signals to the first to M-th columns under the control of the processor, and a priority encoder connected to the first to N-th rows. A first row among the first to N-th rows includes first to M-th memory transistors respectively connected to the first to M-th columns. The first memory transistor among the first to M-th memory transistors includes a first source terminal receiving the first complementary search signal, a first gate terminal receiving the first input signal, a first drain terminal receiving the first search signal, and a first electrical element. When a first code of a codeword corresponding to the first search signal and the first complementary search signal corresponds to a programmed state of the first electrical element, a capacitance value of the first memory transistor is smaller than a threshold value. Each of the ‘N’ and the ‘M’ is an arbitrary natural number.

According to an embodiment, an operating method of a CAM device communicating with a processor includes providing, by a voltage generator, first to N-th input signals to first to N-th rows of a memory cell array under control of the processor, respectively, and providing, by a driver circuit, first to M-th search signals to first to M-th columns of the memory cell array, respectively, and providing first to M-th complementary search signals to the first to M-th column, respectively, under the control of the processor. A first row among the first to N-th rows includes first to M-th memory transistors respectively connected to the first to M-th columns. The first memory transistor among the first to M-th memory transistors includes a first source terminal receiving the first complementary search signal, a first gate terminal receiving the first input signal, a first drain terminal receiving the first search signal, and a first electrical element. When a first code of a codeword corresponding to the first search signal and the first complementary search signal corresponds to a programmed state of the first electrical element, a capacitance value of the first memory transistor is smaller than a threshold value. Each of the ‘N’ and the ‘M’ is an arbitrary natural number.

According to an embodiment, a CAM system includes a CAM device, and a processor that controls the CAM device. The CAM device includes a memory cell array including first to N-th rows and first to M-th columns, a voltage generator that respectively provides first to N-th input signals to the first to N-th rows under control of the processor, a driver circuit that respectively provides first to M-th search signals to the first to M-th columns and respectively provides first to M-th complementary search signals to the first to M-th columns under the control of the processor, and a priority encoder connected to the first to N-th rows. A first row among the first to N-th rows includes first to M-th memory transistors respectively connected to the first to M-th columns. The first memory transistor among the first to M-th memory transistors includes a first source terminal receiving the first complementary search signal, a first gate terminal receiving the first input signal, a first drain terminal receiving the first search signal, and a first electrical element. When a first code of a codeword corresponding to the first search signal and the first complementary search signal corresponds to a programmed state of the first electrical element, a capacitance value of the first memory transistor is smaller than a threshold value. Each of the ‘N’ and the ‘M’ is an arbitrary natural number.

### BRIEF DESCRIPTION OF THE FIGURES

The above and other objects and features of the present disclosure will become apparent by describing in detail embodiments thereof with reference to the accompanying drawings.

FIG. 1 is a block diagram showing a CAM device, according to an embodiment of the present disclosure.

FIG. 2A is a diagram showing an example of a CAM device based on a ferroelectric field effect transistor (FeFET).

FIG. 2B is a graph for describing characteristics of a FeFET element of the CAM device of FIG. 2A.

FIG. 2C is a graph for describing a CAM operation of the CAM device of FIG. 2A.

FIG. 3 is a block diagram illustrating an example of a part of the CAM device of FIG. 1.

FIG. 4 is a graph showing operating characteristics of the first memory transistor of FIG. 3.

FIG. 5 is a graph for describing a propagation delay time of the CAM device of FIG. 3.

FIG. 6 is a drawing showing an equivalent circuit of FIG. 3.

FIG. 7 is a diagram for describing an operation of searching for data stored in the first memory cell group of FIG. 3.

FIG. 8 is a diagram for describing a propagation delay time corresponding to a first match line of FIG. 3.

FIG. 9 is a diagram showing an example of a ferroelectric tunnel field-effect transistor (FeTFET) element.

FIGS. 10A and 10B are drawings for describing an operation of a first memory cell including a FeTFET.

FIG. 11 is a drawing for describing an operating method of the CAM device of FIG. 1.

### DETAILED DESCRIPTION

Hereinafter, embodiments of the present disclosure will be described in detail and clearly to such an extent that an ordinary one in the art easily implements the present disclosure.

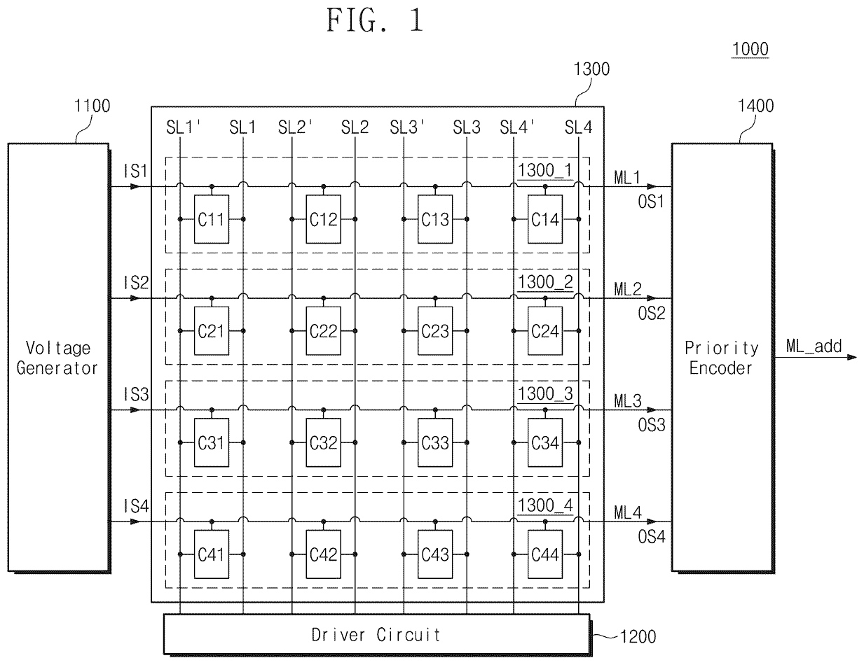

FIG. 1 is a block diagram showing a content addressable memory (CAM) device (hereinafter referred to as a “CAM device”), according to an embodiment of the present disclosure. Referring to FIG. 1, a CAM device 1000 may include a voltage generator 1100, a driver circuit 1200, a memory cell array 1300, and a priority encoder 1400. The memory cell array 1300 may include a plurality of rows and a plurality of columns. For example, the memory cell array 1300 may include first to N-th rows and first to M-th columns. At this time, each of ‘N’ and ‘M’ may be an arbitrary natural number. For convenience of description, FIG. 1 shows that the memory cell array 1300 includes first to fourth rows and first to fourth columns. The first to fourth rows may be referred to as “first to fourth memory cell groups 1300_1 to 1300_4”, respectively.

In some embodiments, the CAM device 1000 may communicate with a processor (not shown). The processor may control the voltage generator 1100 and the driver circuit 1200. The processor may provide a codeword (alternatively, search data or input data) to the driver circuit 1200. The codeword refers to data to be found from among data stored in the memory cell array 1300. Hereinafter, the codeword is used as the same meaning as search data and input data. For example, an M-length codeword may include first to M-th codes. In FIG. 1, for convenience of description, it is described that the processor provides a codeword including first to fourth codes to the driver circuit 1200.

The voltage generator 1100 may generate first to N-th input signals under control of the processor. For example, the voltage generator 1100 may provide first to fourth input signals IS1 to IS4 to the first to fourth memory cell groups 1300_1 to 1300_4 through first to fourth match lines ML1 to ML4, respectively. In some embodiments, each of the first to fourth input signals IS1 to IS4 may include a voltage pulse. The driver circuit 1200 may receive the codeword from the processor. The driver circuit 1200 may generate first to fourth search signals and first to fourth complementary search signals, which correspond to the codeword, based on the codeword. The driver circuit 1200 may provide the first to fourth search signals to first to fourth columns through the first to fourth search lines SL1 to SL4, respectively. The driver circuit 1200 may provide the first to fourth complementary search signals to the first to fourth columns through first to fourth complementary search lines SL1′ to SL4′, respectively.

The first memory cell group 1300_1 may include first to fourth memory cells C11 to C14. The second memory cell group 1300_2 may include fifth to eighth memory cells C21 to C24. The third memory cell group 1300_3 may include ninth to twelfth memory cells C31 to C34. The fourth memory cell group 1300_4 may include thirteenth to sixteenth memory cells C41 to C44. Here, the number of memory cells illustrated in FIG. 1 is only one example, and the number of memory cells may be determined depending on sizes of various codewords such as 32 to 256 bits. Also, the number of search lines thus illustrated may be changed depending on the size of a codeword.

Each of the first to sixteenth memory cells C11 to C44 may include a memory transistor.

In some embodiments, a transistor included in each of the first to sixteenth memory cells C11 to C44 may have electrical characteristics (i.e., bipolar) that have capacitance lower than a threshold value in a specific gate voltage level section (e.g., higher than or equal to a first voltage level and lower than or equal to a second voltage level) and have capacitance higher than the threshold value in the other gate voltage level sections.

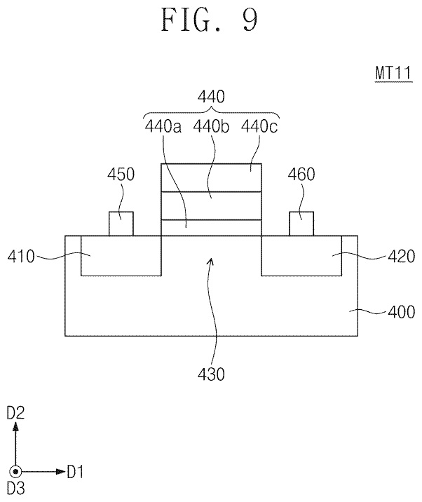

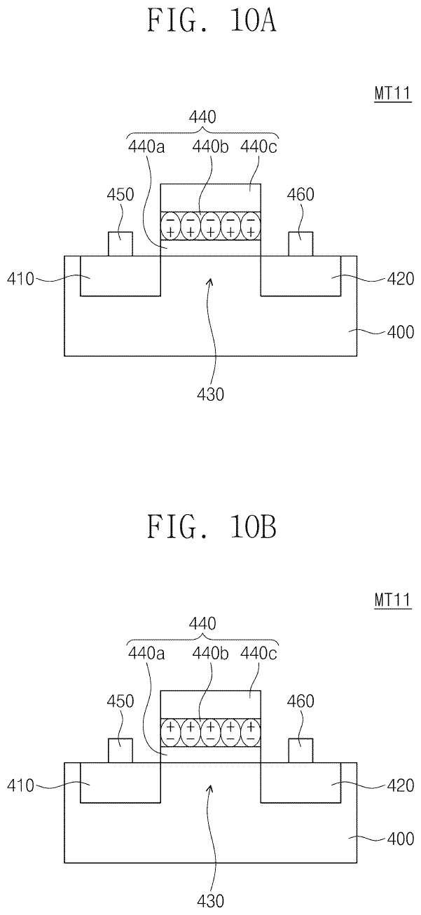

In some embodiments, the transistor included in each of the first to sixteenth memory cells C11 to C44 may be a ferroelectric tunnel field-effect transistor (FeTFET). A more detailed description of the FeTFET device will be described later with reference to FIGS. 9, 10A, and 10B.

In some embodiments, each of the first to sixteenth memory cells C11 to C44 may store 1 bit or 2 bits. However, the scope of the present disclosure is not limited thereto, and the number of bits stored in a memory cell may increase or decrease depending on implementation. For convenience of description, hereinafter, it is assumed that each of the first to sixteenth memory cells C11 to C44 stores 1 bit. For example, each of the first to sixteenth memory cells C11 to C44 may store one of a bit value ‘1’ and a bit value ‘0’.

In some embodiments, the CAM device 1000 may include first to fourth resistance components (not shown) connected between the voltage generator 1100 and the memory cell array 1300. For example, the first resistance component may be connected between the voltage generator 1100 and the first memory cell group 1300_1. The first resistance component may transmit the first input signal IS1 received from the voltage generator 1100 to the first match line ML1. The resistance component may refer to an electrical element with a resistance value, and the resistance value of the resistance component is not affected by the matching at each match line. The CAM device 1000 may improve the resolution of the priority encoder 1400 by adjusting resistance values of the resistance components. The resolution may correspond to a difference between propagation delay times of the match lines ML1 to ML4.

The priority encoder 1400 may output the address of a memory cell array having data matching the codeword as a match address ML_add based on first to fourth output signals OS1 to OS4 respectively output from the first to fourth memory cell groups 1300_1 to 1300_4 of the memory cell array 1300. For example, the first to fourth output signals OS1 to OS4 may refer to electrical signals obtained as the first to fourth input signals IS1 to IS4 are respectively propagated through match lines and then reach the priority encoder 1400. The first to fourth output signals OS1 to OS4 may include voltage pulses corresponding to the first to fourth input signals IS1 to IS4, respectively.

For example, the priority encoder 1400 may determine a row, which matches the codeword, from among the first to fourth rows based on the first to fourth output signals OS1 to OS4. In detail, a memory cell group, in which stored data (stored bits) matches the codeword, from among the first to fourth memory cell groups 1300_1 to 1300_4 may be determined. When there are a plurality of matching rows, the priority encoder 1400 may output the address of one row depending on a priority algorithm.

For example, it is assumed that a codeword is ‘1 0 1 0’; the first memory cell C11 stores ‘1’; the second memory cell C12 stores ‘0’; the third memory cell C13 stores ‘1’; the fourth memory cell C14 stores ‘0’; the fifth memory cell C21 stores ‘1’; the sixth memory cell C22 stores ‘0’; the seventh memory cell C23 stores ‘1’; the eighth memory cell C24 stores ‘1’; the ninth memory cell C31 stores ‘1’; the tenth memory cell C32 stores ‘0’; the eleventh memory cell C33 stores ‘0’; the twelfth memory cell C34 stores ‘1’; the thirteenth memory cell C41 stores ‘1’; the fourteenth memory cell C42 stores ‘1’; the fifteenth memory cell C43 stores ‘0’; and the sixteenth memory cell C44 stores ‘1’.

The priority encoder 1400 may determine a row, which matches the codeword, based on propagation delay times of the first to fourth rows. The propagation delay time may refer to the time required for an input signal to be propagated through a match line and to reach the priority encoder.

In some embodiments, first to fourth propagation delay signals may be calculated based on an operation of comparing between the first to fourth output signals OS1 to OS4 and the first to fourth input signals IS1 to IS4.

For example, the priority encoder 1400 may calculate the first propagation delay time based on a time difference between the first input signal IS1 and the first output signal OS1. In detail, the length of a time interval between a first time point of the first input signal IS1 and a second time point of the first output signal OS1 may be determined as the first propagation delay time. The first time point may be a time point at which a first edge of the first input signal IS1 occurs. The second time point may be a time point at which a second edge of the first output signal OS1 occurs in response to the first edge. As in the above description, the priority encoder 1400 may calculate second to fourth propagation delay times based on the second to fourth input signals IS2 to IS4 and the second to fourth output signals OS2 to OS4, respectively.

As the number of bits (the number of mismatch bits) that data stored in the corresponding row mismatches the codeword is greater, each of the first to fourth propagation delay times becomes longer. Accordingly, the priority encoder 1400 may determine the number of (or mismatch) bits mismatched between a codeword and data, which is stored by each of the first to fourth memory cell groups 1300_1 to 1300_4, based on the first to fourth propagation delay times.

For example, the priority encoder 1400 may determine the number of bits mismatched between the codeword and the data, which is stored by the first memory cell group 1300_1, based on the first propagation delay signal.

In some embodiments, the priority encoder 1400 may determine that the number of mismatch bits is increased as the propagation delay time is long. For example, as the number of mismatch bits increases, the propagation delay time may increase linearly.

In some embodiments, the memory cell array 1300 may further include first to fourth input inverter circuits (not shown) connected between the voltage generator 1100 and the first to fourth memory cell groups 1300_1 to 1300_4, respectively. The first to fourth input inverter circuits may receive the first to fourth input signals IS1 to IS4, and may provide inverted input signals to the memory cell groups 1300_1 to 1300_4 through the first to fourth match lines ML1 to ML4, respectively. Each of the first to fourth input inverter circuits may be connected to a VDD voltage, and thus the VDD voltage may be provided to the first to fourth match lines ML1 to ML4.

For example, the first inverter circuit may receive the first input signal IS1 and the first inverter circuit may provide the inverted first input signal, which is obtained by inverting the first input signal IS1, to the first memory cell group 1300_1 through the first match line ML1. Each of the second to fourth inverter circuits may operate as in the above description.

In some embodiments, the memory cell array 1300 may further include first to fourth output inverter circuits (not shown) connected between the priority encoder 1400 and the first to fourth memory cell groups 1300_1 to 1300_4, respectively. The first to fourth output inverter circuits may be respectively connected to the first to fourth match lines ML1 to ML4 and may respectively provide the first to fourth output signals OS1 to OS4 to the priority encoder 1400. Each of the first to fourth output inverter circuits are connected to the VDD voltage, and thus the VDD voltage may be provided to the first to fourth match lines ML1 to ML4.

For example, the first output inverter circuit may be connected to the first match line ML1 to receive the propagated first input signal IS1 (or the inverted first input signal when there is a first input inverter), and to provide the first output signal OS1 to the priority encoder 1400. Each of the second to fourth output inverter circuits may operate as in the above description.

In some embodiments, the memory cell array 1300 may further include first to fourth time-to-digital convertor (TDC) circuits (not shown). The first to fourth TDC circuits may be connected between the priority encoder 1400 and the first to fourth memory cell groups 1300_1 to 1300_4, respectively. As described above, when the first to fourth output inverter circuits are included, the first to fourth TDC circuits may be connected between the priority encoder 1400 and the first to fourth output inverter circuits, respectively.

For example, the first TDC circuit may be connected between the first output inverter circuit and the priority encoder 1400. The first TDC circuit may receive the first output signal OS1 from the first output inverter circuit. The first TDC circuit may convert a propagation delay time into digital data based on the first input signal IS1 and the first output signal OS1. The first TDC circuit may provide the digital data corresponding to the propagation delay time to the priority encoder 1400. The priority encoder 1400 may output the address of a match line, which matches the codeword, based on the digital data received from each of the first to fourth TDC circuits.

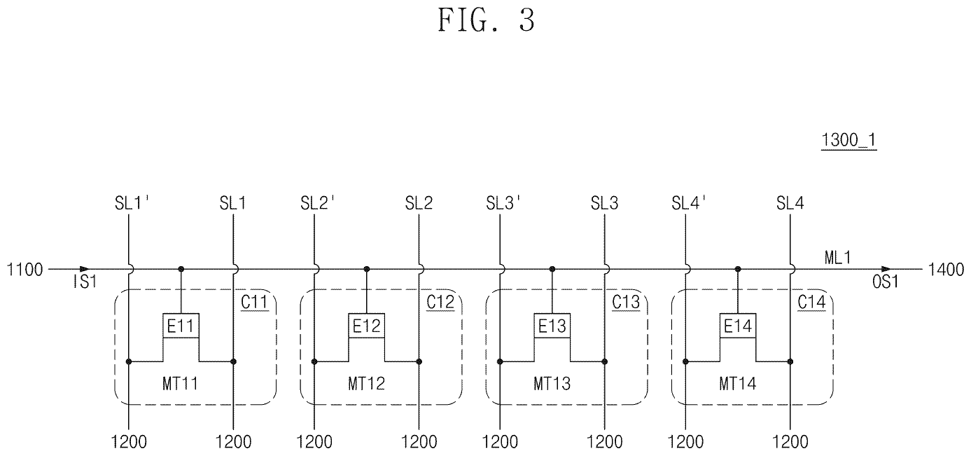

For another example, the first to fourth TDC circuits may be included in the priority encoder 1400. The driver circuit 1200 may provide a first search signal and a first complementary search signal, which correspond to the first code ‘1’ of the codeword, to the first search line SL1 and the first complementary search line SL1′, respectively. As in the above description, the driver circuit 1200 may provide a second search signal and a second complementary search signal, which correspond to the second code ‘0’ of the codeword, to the second search line SL2 and the second complementary search line SL2′, respectively; the driver circuit 1200 may provide a third search signal and a third complementary search signal, which correspond to the third code ‘1’, to the third search line SL3 and the third complementary search line SL3′, respectively; and the driver circuit 1200 may provide a fourth search signal and a fourth complementary search signal, which correspond to the fourth code ‘0’, to the fourth search line SL4 and the fourth complementary search line SL4′, respectively. Detailed descriptions thereof will be described later with reference to FIG. 4.

Each of the first, fifth, ninth, and thirteenth memory cells C11, C21, C31, and C41 may receive the first code ‘1’ of the codeword through the first search line SL1 and the first complementary search line SL1′, respectively. Each of the second, sixth, tenth, and fourteenth memory cells C12, C22, C32, and C42 may receive the second code ‘0’ through the second search line SL2 and the second complementary search line SL2′, respectively. Each of the third, seventh, eleventh, and fifteenth memory cells C13, C23, C33, and C43 may receive the third code ‘1’ through the third search line SL3 and the third complementary search line SL3′, respectively. Each of the fourth, eighth, twelfth, and sixteenth memory cells C14, C24, C34, and C44 may receive the second code ‘0’ through the fourth search line SL4 and the fourth complementary search line SL4′, respectively.

In some embodiments, each of the first to sixteenth memory cells C11 to C44 may include an electrical element with a programmed state so as to correspond to the stored bit value. The programmed state may refer to one of a first bit value or a second bit value.

In other words, each of the first to sixteenth memory cells C11 to C44 may store (or program) one of the first bit value and the second bit value. Each of the first to sixteenth memory cells C11 to C44 may have capacitance lower than a threshold value when the stored bits correspond to a codeword. For example, the capacitance may refer to capacitance between a gate terminal of a memory transistor and a ground terminal.

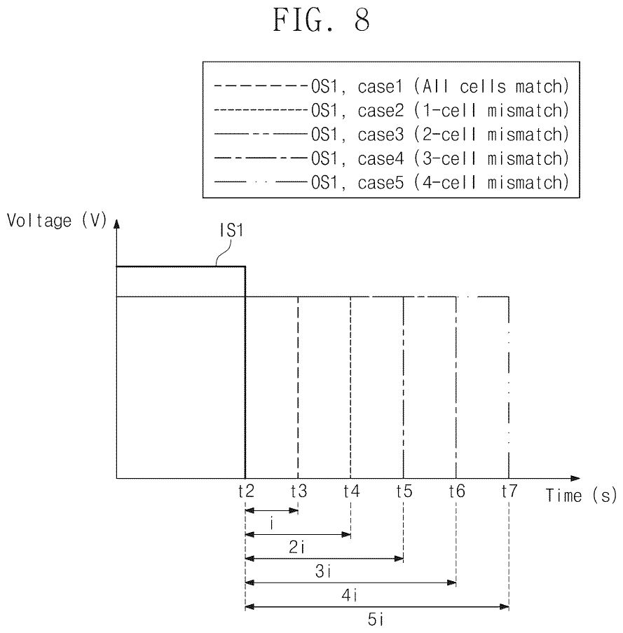

As the number of mismatch bits increases in each of the first to fourth memory cell groups 1300_1 to 1300_4, the capacitance value between the match line and the ground terminal may increase. Accordingly, as the number of mismatch bits increases in each of the first to fourth memory cell groups 1300_1 to 1300_4, the propagation delay time may increase. Detailed descriptions thereof will be described later with reference to FIG. 8.

The priority encoder 1400 may output an address corresponding to a first memory cell group 1300_1, which has the smallest number of mismatch bits (i.e., storing the same data as the codeword ‘1 0 1 0’), from among the first to fourth memory cell groups 1300_1 to 1300_4 as the match address ML_add.

In some embodiments, a CAM system including the CAM device 1000 of FIG. 1 and a processor that controls the same may be provided. For example, the CAM system may be implemented as an electronic system such as a PC, a tablet PC, a smartphone, a data center, a server device, or the like.

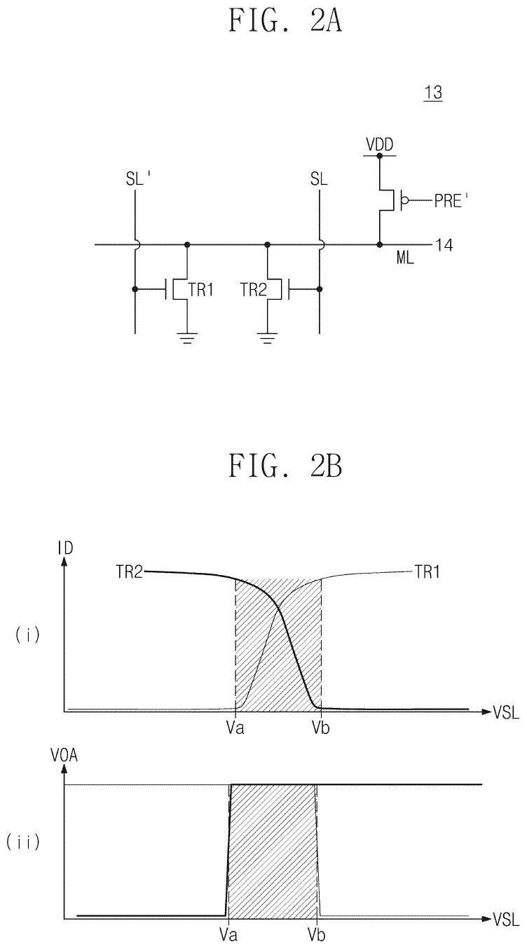

FIG. 2A is a diagram showing an example of a CAM device 13 based on a ferroelectric field effect transistor (FeFET). Briefly, a match line ML is provided, and two FeFET elements TR1 and TR2 connected to the match line ML are placed in parallel. A search line SL and a complementary search line (or search line bar) SL′ are connected to the two FeFET elements, respectively. The Two FeFET elements constitute one memory cell of the CAM device 13. In addition, the CAM device 13 may further include a pre-charge unit PRE, which applies a VDD voltage to the match line, and a sense amplifier 14.

FIG. 2B is a graph for describing characteristics of a FeFET element of the CAM device of FIG. 2A. A graph (i) of FIG. 2B shows a drain current ID relative to a gate voltage VSL applied through a search line, and a graph (ii) of FIG. 2B shows a voltage VOA of an output terminal of the sense amplifier 14 relative to the gate voltage VSL applied through the search line.

Referring to FIG. 2B, it may be understood that two transistors have opposite voltages in a section other than a specific voltage section (a section between Va and Vb). As such, to implement a high-pass filter or a low-pass filter that allows or blocks a current depending on a gate voltage higher or lower than a threshold voltage, as shown in FIG. 2A, the FeFET element is required to combine the two FeFET elements in parallel.

FIG. 2C is a graph for describing a CAM operation of the CAM device of FIG. 2A. The CAM device in FIG. 2A may determine the number of mismatch bits in each memory cell group based on a speed at which a match line voltage MLV detected at the match line drops from a precharge voltage Vpre.

For example, when all the data stored in a memory cell group matches the codeword (e.g., when the number of mismatch bits is 0), the match line voltage MLV may not decrease significantly. On the other hand, when the data stored in the memory cell group does not match the codeword, the match line voltage MLV may be discharged from the precharge voltage Vpre. As the number of mismatch bits is great, the discharge speed of the match line voltage MLV may be fast.

As shown in drawings, a voltage change in the match line voltage MLV may nonlinearly vary over time. Accordingly, the CAM device in FIG. 2A needs to perform a nonlinear operation to determine the number of mismatch bits.

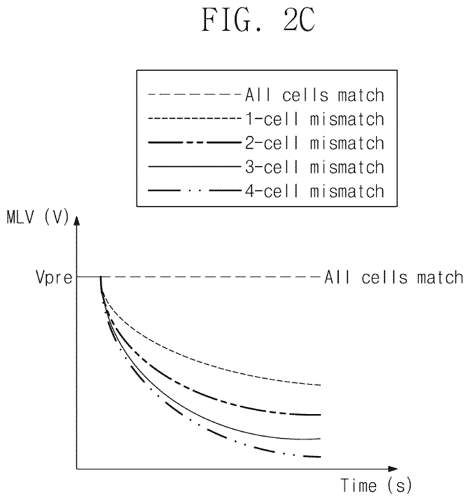

FIG. 3 is a block diagram illustrating an example of a part of the CAM device of FIG. 1. For brevity of drawing and for convenience of description, only the first memory cell group 1300_1 of FIG. 1 is shown in FIG. 3. The other memory cell groups 1300_2 to 1300_4 may be the same as or similar to the first memory cell group 1300_1.

The first memory cell group 1300_1 may receive the first input signal IS1 from the voltage generator 1100 of FIG. 1 through the first match line ML1. The first memory cell group 1300_1 may output the first output signal OS1 to the priority encoder 1400 through the first match line ML1.

Each of the first to fourth memory cells C11 to C14 may include a memory transistor. For example, the first memory cell C11 may include a first memory transistor MT11. The second memory cell C12 may include a second memory transistor MT12. The third memory cell C13 may include a third memory transistor MT13. The fourth memory cell C14 may include a fourth memory transistor MT14.

The first memory transistor MT11 may include a first source terminal connected to the first complementary search line SL1′, a first gate terminal connected to the first match line ML1, a first drain terminal connected to the first search line SL1, and a first electrical element EE1.

The second memory transistor MT12 may include a second source terminal connected to the second complementary search line SL2′, a second gate terminal connected to the first match line ML1, a second drain terminal connected to the second search line SL2, and a second electrical element EE2.

The third memory transistor MT13 may include a third source terminal connected to the third complementary search line SL3′, a third gate terminal connected to the first match line ML1, a third drain terminal connected to the third search line SL3, and a third electrical element EE3.

The fourth memory transistor MT14 may include a fourth source terminal connected to the fourth complementary search line SL4′, a fourth gate terminal connected to the first match line ML1, a fourth drain terminal connected to the fourth search line SL4, and a fourth electrical element EE4.

Each of the first to fourth electrical elements EE1 to EE4 may be programmed to store one of a first bit value or a second bit value.

For example, the first electrical element EE1 may correspond to a state that either a bit value ‘1’ or a bit value ‘0’ is stored. Each of the other electrical elements EE2 to EE4 is similar to the first electrical element EE1.

In some embodiments, each of the first to fourth memory transistors MT11 to MT14 may be a FeTFET, and each of the first to fourth electrical elements EE1 to EE4 may refer to a ferroelectric layer of the FeTFET. A more detailed description thereof will be described later with reference to FIGS. 9, 10A, and 10B.

In some embodiments, when the stored bit value corresponds to the first code of the codeword, the capacitance value of the first memory transistor MT11 may be smaller than a threshold value. On the other hand, when the stored bit does not match the codeword, the capacitance value may be greater than the threshold value. The driver circuit 1200 may provide a first search signal and a first complementary search signal, which correspond to the first code of the codeword, to the first memory cell group 1300_1 through the first search line SL1 and the first complementary search line SL1′, respectively. As in the above description, when each of the second to fourth memory transistors MT12 to MT14 stores a bit matching the codeword, the capacitance value of the memory transistor may be smaller than the threshold value. Detailed descriptions thereof will be described later with reference to FIG. 4.

FIG. 4 is a graph showing operating characteristics of the first memory transistor MT11 of FIG. 3. For convenience of description, in FIG. 4, an electrical characteristic between capacitance and a gate voltage of the first memory transistor MT11 of FIG. 3 is described. The other memory transistors MT12 to MT14 in FIG. 3 also have the same electrical characteristics as the first memory transistor MT11. Referring to FIGS. 3 and 4, in this case, a capacitance value Cgg1 indicating a vertical axis may refer to a capacitance value between a gate terminal of the first memory transistor MT11 and a ground terminal, and a gate voltage Vg1 indicating a horizontal axis may refer to a voltage between a first gate terminal and a first source terminal of the first memory transistor, or a voltage between the first gate terminal and a first drain terminal of the first memory transistor.

The first memory transistor may have a capacitance value smaller than a threshold value in a specific gate voltage section and may have a capacitance value greater than the threshold value in the other gate voltages.

For example, when the gate voltage level Vg1 is higher than or equal to a first voltage level V1 and lower than or equal to a second voltage level V2, the capacitance value Cgg1 of the first memory transistor may be smaller than or equal to a threshold value Cr. Otherwise (when the gate voltage level Vg1 is lower than the first voltage level or higher than the second voltage level), the capacitance value Cgg1 may be greater than the threshold value Cr.

In other words, as illustrated in FIG. 4, the first memory transistor may have electrical characteristics (i.e., bipolar) with small capacitance only at a specific gate voltage.

In this case, the specific gate voltage section may vary depending on a programmed state (a stored bit value) of the first memory transistor.

When the first memory transistor stores a bit value ‘1’, the capacitance value Cgg1 of the first memory transistor may be smaller than or equal to the threshold value Cr at the gate voltage level Vg1 that is higher than or equal to the first voltage level V1 and is lower than or equal to the second voltage level V2. On the other hand, when the first memory transistor stores a bit value ‘0’, the capacitance value Cgg1 of the first memory transistor may be smaller than or equal to the threshold value Cr at the gate voltage level Vg1 that is higher than or equal to a third voltage level V3 and is lower than or equal to a fourth voltage level V4. In this case, the third voltage level V3 may be higher than the first voltage level V1, and the fourth voltage level V4 may be higher than the second voltage level V2.

Accordingly, when the gate voltage level Vg1, at which the capacitance value Cgg1 is identified depending on a bit value stored in the first memory transistor, is used, whether the stored bit value matches a codeword may be determined. The gate voltage level Vg1 may be determined based on a first search line signal, a first input signal, and a first complementary search line signal.

For example, when the first code of the codeword is ‘1’, the driver circuit may provide the first search line signal and the first complementary search line signal such that the gate voltage level Vg1 of the first memory transistor is higher than the first voltage level V1 and lower than the third voltage level V3. The gate voltage level capable of determining whether a bit stored in the first memory transistor corresponds to a first code ‘1’ may be referred to as a “search voltage Vs1”. In this case, when storing a bit value ‘1’ that matches the first code, the first memory transistor may have a capacitance value smaller than the threshold value Cr. When storing a bit value ‘0’ that does not match the first code, the first memory transistor may have a capacitance value greater than the threshold value Cr.

For another example, when the first code of the codeword is ‘0’, the driver circuit may provide the first search line signal and the first complementary search line signal such that the gate voltage level Vg1 of the first memory transistor is higher than the second voltage level V2 and lower than the fourth voltage level V4. The gate voltage level capable of determining whether the bit stored in the first memory transistor corresponds to the first code ‘0’ may be referred to as a “search voltage Vs0”. In this case, when storing a bit value ‘0’ that matches the first code, the first memory transistor may have a capacitance value smaller than the threshold value Cr. When storing a bit value ‘1’ that does not match the first code, the first memory transistor may have a capacitance value greater than the threshold value Cr.

In other words, the first memory cell C11 may determine whether the stored bit value matches the codeword, by using only one memory transistor (the first memory transistor). Accordingly, unlike a conventional CAM device that requires at least two or more transistors per memory cell, the CAM device according to an embodiment of the present disclosure may be miniaturized or highly integrated, and the power consumption thereof may be reduced.

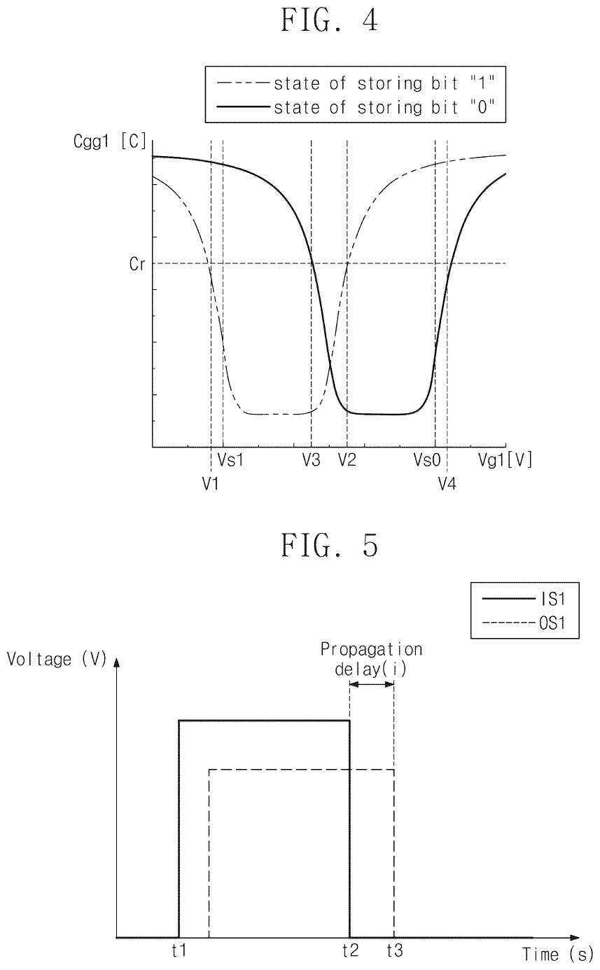

FIG. 5 is a graph for describing a propagation delay time of the CAM device of FIG. 3. Referring to FIG. 5, the first input signal IS1 and the first output signal OS1 of FIG. 3 are described. A horizontal axis of FIG. 5 represents time, and a vertical axis represents a voltage level.

The first input signal IS1 may include a voltage pulse. For example, the first input signal IS1 may include a voltage pulse that has a rising edge at a first time point t1 and a falling edge at a second time point t2.

Similarly to the first input signal IS1, the first output signal OS1 may include rising and falling edges. However, the first output signal OS1 differs from the first input signal IS1 in that the first output signal OS1 is propagated through the first match line ML1, which is connected to a plurality of electrical elements (e.g., first to fourth memory cells). For example, compared to the first input signal IS1, the first output signal OS1 is delayed by a propagation delay time.

In detail, the falling edge of the first output signal OS1 may appear at a third time point t3 later than the second time point t2, at which the falling edge of the first input signal IS1 occurs, by a propagation delay time ‘i’.

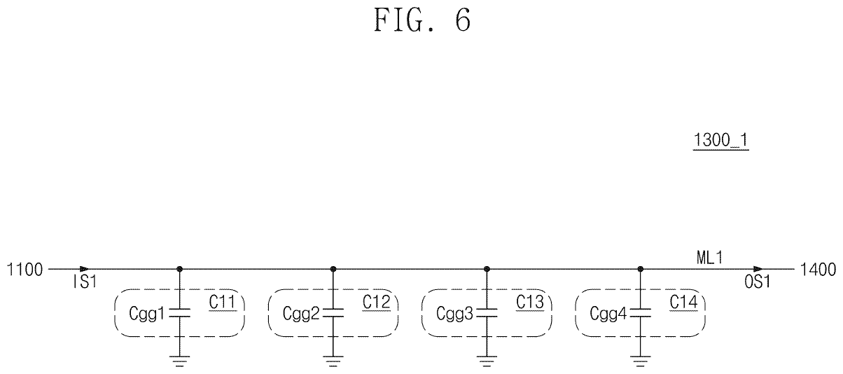

As a value of capacitance loaded into the first match line ML1 increases, the propagation delay time ‘i’ may increase. That is, as the number of mismatch bits increases, the propagation delay time ‘i’ may increase. This will be more fully described with reference to FIGS. 6 to 8.

FIG. 6 is a drawing showing an equivalent circuit of FIG. 3. Referring to FIG. 6, an equivalent circuit of the first memory cell group 1300_1 is shown. The first memory cell group 1300_1 may be an equivalent circuit of the first memory cell group 1300_1 of FIG. 3.

The first memory cell C11 may be illustrated as including a first capacitor. The first capacitor may have the first capacitance value Cgg1 and may be connected between a first gate terminal and a ground terminal. The second memory cell C12 may be illustrated as including a second capacitor. The second capacitor may have a second capacitance value Cgg2 and may be connected between a second gate terminal and the ground terminal. The third capacitor may have a third capacitance value Cgg3 and may be connected between a third gate terminal and the ground terminal. The fourth capacitor may have a fourth capacitance value Cgg4 and may be connected between a fourth gate terminal and the ground terminal. For ease of description, each of the first to fourth capacitors is described as being connected to the ground terminal, but this may vary depending on circuit design methods.

The first to fourth capacitors are connected in parallel between the first match line ML1 and the ground terminal. Accordingly, the capacitance value loaded on the match line may be equal to the sum of the pieces of capacitance Cgg1 to Cgg4 of the first to fourth capacitors.

In some embodiments, the value of the capacitance between the first match line ML1 and the ground terminal may increase linearly with the number of mismatch bits.

For example, it is assumed that the first capacitance value of the memory transistor storing a value matching a bit value of a codeword is smaller than a threshold value, and the second capacitance value of the memory transistor storing a value that does not match the bit value of the codeword is greater than the threshold value. As the number of memory cells, which have bit values that do not match bit values of the codeword, from among the memory cells C11 to C14 in the first memory cell group 1300_1 increases, the capacitance value loaded into the first match line ML1 may increase by a difference between the first capacitance value and the second capacitance value. That is, the capacitance value loaded into the first match line ML1 may increase linearly depending on the number of bits that mismatch the codeword.

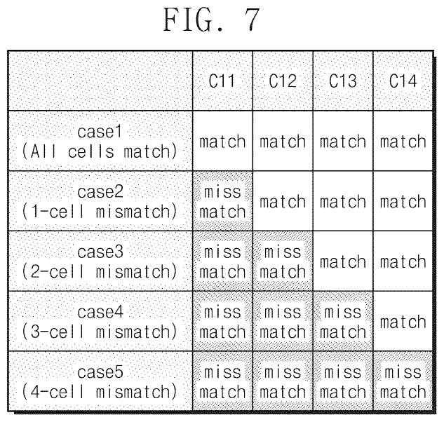

FIG. 7 is a diagram for describing an operation of searching for data stored in the first memory cell group of FIG. 3. Referring to FIG. 7, first to fifth cases with different numbers of mismatch bits are described.

For convenience of description, in a first memory cell group including the first to fourth memory cells C11 to C14, the first to fifth cases are described as possible cases. However, the scope of the present disclosure is not limited thereto. For example, the number of cases may increase or decrease as the memory cells change.

The first case may refer to a case where data stored in all the memory cells C11 to C14 of the first memory cell group matches a codeword.

In detail, a bit value stored in the first memory cell C11 corresponds to a first code of the codeword; a bit value stored in the second memory cell C12 corresponds to a second code of the codeword; a bit value stored in the third memory cell C13 corresponds to a third code of the codeword; and a bit value stored in the fourth memory cell C14 corresponds to a fourth code of the codeword. In this case, each of capacitance values of the first to fourth memory cells C11 to C14 may have a first capacitance value smaller than a threshold value.

The second case may refer to a case where the number of memory cells, which do not match the codeword, from among all the memory cells C11 to C14 of the first memory cell group is 1.

In detail, bit value stored in the second to fourth memory cells C12 to C14 correspond to the second to fourth codes of the codeword, respectively. However, the bit value stored by the first memory cell C11 may not correspond to the first code of the codeword. In this case, the capacitance value of the first memory transistor MT11 may be a second capacitance value greater than the threshold value. Each of the capacitance values of the second to fourth memory transistors MT12 to MT14 may be the first capacitance value smaller than the threshold value.

The third case may refer to a case where the number of memory cells, which do not match the codeword, from among all the memory cells C11 to C14 of the first memory cell group is 2.

In detail, bit values stored in the third and fourth memory cells C13 and C14 correspond to the third and fourth codes of the codeword, respectively. However, bit values stored in the first and second memory cells C11 and C12 may not correspond to the first and second codes of the codeword, respectively. In this case, each of the capacitance values of the first and second memory transistors MT11 and MT12 may be the second capacitance value. Each of the capacitance values of the third and fourth memory transistors MT13 and MT14 may be the first capacitance value.

The fourth case may refer to a case where the number of memory cells, which do not match the codeword, from among all the memory cells C11 to C14 of the first memory cell group is 3.

In detail, a bit value stored by the fourth memory cell C14 may correspond to the fourth code of the codeword. However, bit values stored in the first to third memory cells C11 and C13 may not correspond to the first to third codes of the codeword, respectively. In this case, each of the capacitance values of the first to third memory transistors MT11 to MT13 may be the second capacitance value. The capacitance value of the fourth memory transistor MT14 may be the first capacitance value.

The fifth case may refer to a case where all the data stored in all the memory cells C11 to C14 of the first memory cell group do not match the codeword.

In detail, the bit value stored in the first memory cell C11 does not correspond to the first code of the codeword; the bit value stored in the second memory cell C12 does not correspond to the second code of the codeword; the bit value stored in the third memory cell C13 does not correspond to the third code of the codeword; and the bit value stored in the fourth memory cell C14 does not correspond to the fourth code of the codeword. In this case, each of the capacitance values of the first to fourth memory transistors MT11 to MT14 may be the second capacitance value.

In other words, as the number of mismatch bits increases, the capacitance value loaded on the match line may increase linearly.

FIG. 8 is a diagram for describing a propagation delay time according to the number of mismatch bits. Referring to FIG. 8, a propagation delay time for each of the first to fifth cases in FIG. 7 is described. In FIG. 8, a horizontal axis represents a time, and a vertical axis represents a voltage.

The first input signal IS1 (corresponding to the first input signal in FIGS. 3 and 5) has a falling edge at the second time point t2.

As a capacitance value loaded in the first match line is greater, the propagation delay time is longer. That is, as the number of mismatch bits increases, a capacitance value between the first match line ML1 and a ground terminal increases.

In some embodiments, as the number of mismatch bits increases, the capacitance value between the first match line ML1 and the ground terminal may increase linearly. In this case, a capacitance value of the memory transistor storing a bit value that does not match the codeword may be set as a first capacitance value, and a capacitance value of the memory transistor storing a bit value that matches the codeword may be set as a second capacitance value. (A search line signal and a complementary search line signal may be set). Accordingly, as the number of mismatch bits increases, the propagation delay time may increase linearly.

For example, in the first case where the number of mismatch bits is 0, the propagation delay time is a time ‘i’ between the second time point t2 and the third time point t3. In the second case where the number of mismatch bits is 1, the propagation delay time is a time ‘2i’ between the second time point t2 and a fourth time point t4. In the third case where the number of mismatch bits is 2, the propagation delay time is a time ‘3i’ between the second time point t2 and a fifth time point t5. In the fourth case where the number of mismatch bits is 3, the propagation delay time is a time ‘4i’ between the second time point t2 and a sixth time point t6. In the fifth case where the number of mismatch bits is 4, the propagation delay time is a time ‘5i’ between the second time point t2 and a seventh time point t7.

That is, as the number of mismatch bits increases by one, the propagation delay time increases linearly by ‘i’.

The CAM device according to an embodiment of the present disclosure may output an address of a memory cell array matching the codeword based on the propagation delay time. In detail, the priority encoder in FIG. 1 may calculate the propagation delay time based on an operation of comparing between an input signal and an output signal of each match line, and may determine the number of mismatch bits of a row connected to the match line based on the propagation delay time. In this case, the priority encoder may determine the number of mismatch bits based on only the linear operation, thereby simplifying and speeding up CAM operations. The priority encoder may output the address of a row having the number of mismatch bits of 0 as a match address based on the number of mismatch bits in each of a plurality of rows or may output the address of a row having the least number of mismatch bits as the match address.

FIG. 9 is a diagram showing an example of a ferroelectric tunnel field-effect transistor (FeTFET) element. Referring to FIG. 9, when the first memory transistor MT11 in FIG. 3 is a FeTFET, a FeTFET element is described. The first to fourth memory transistors MT11 to MT14 of FIG. 3 are configured to be substantially identical to one another and to operate substantially identically to one another. Accordingly, for convenience of description, the first memory transistor MT11 is described as an example. Each of the remaining memory transistors MT12 to MT14 are the same as or similar to the first memory transistor MT11, and thus a detailed description thereof will be omitted to avoid redundancy. A first direction D1 may be parallel to a semiconductor substrate 400 on which the first memory transistor MT11 is implemented. A second direction D2 may be perpendicular to the first direction D1. A third direction D3 may be perpendicular to a plane defined by the first and second directions D1 and D2.

The FeTFET MT11 may include a first doped region 410 and a second doped region 420, which are formed on the semiconductor substrate 400 so as to be spaced from each other by a predetermined distance and may include a channel region 430 formed between the first doped region 410 and the second doped region 420, and a gate 440 formed on the channel region 430. That is, the FeTFET MT11 may include the first doped region 410, the second doped region 420, and the channel region 430, which are formed on the semiconductor substrate 400. The FeTFET MT11 may further include the gate 440, a first electrode 450, and a second electrode 460.

For example, the semiconductor substrate 400 may be a proper semiconductor substrate such as a semiconductor wafer, a silicon-on-insulator substrate, a semiconductor layer formed on the semiconductor substrate, or the like. The semiconductor substrate 400 may be a silicon substrate, but the scope of the present disclosure is not limited thereto. For example, the semiconductor substrate 400 may use other semiconductor materials.

In an embodiment, the semiconductor substrate 400 may be formed as a region (P− region), which is doped with P-type impurities so as to be weaker than the first doped region 410, or an intrinsic region, which is undoped. Alternatively, the semiconductor substrate 400 may be formed as a region (N− region), which is doped with N-type impurities so as to be weaker than the second doped region 420 or an intrinsic region, which is undoped. That is, the semiconductor substrate 400 may be an intrinsic (i-type) silicon substrate.

In an embodiment, the first doped region 410 may have a first conductivity type. For example, the first doped region 410 may have a P+ type. The first doped region 410 may have a first doping concentration. The first doped region 410 may be a source region. The second doped region 420 may have a second conductivity type. For example, the second doped region 420 may have an N+ type. The second doped region 420 may have a second doping concentration. The second doped region 420 may be a drain region.

The first doped region 410 and the second doped region 420 may be spaced from each other in the first direction D1. The first doped region 410 and the second doped region 420 may extend in a direction opposite to the second direction D2 perpendicular to the first direction D1.

In an embodiment, to improve a turn-on operation and a bipolar (or ambipolar) operation, the doping concentration of the first doped region 410 may be adjusted (or changed), or the doping concentration of the second doped region 420 may be adjusted. The first doped region 410 may have a third doping concentration higher than the first doping concentration. Alternatively, the second doped region 420 may have a fourth doping concentration higher than the second doping concentration.

The channel region 430 may be formed as a region (P− region), which is doped with P-type impurities so as to be weaker than the first doped region 410, or an intrinsic region, which is undoped. Alternatively, the channel region 430 may be formed as a region (N− region), which is doped with N-type impurities so as to be weaker than the second doped region 420, or an intrinsic region, which is undoped.

The gate 440 may be disposed on a top surface of the channel region 430. The gate 440 may be formed by sequentially stacking a gate insulating layer 440a, a ferroelectric layer 440b, and a gate electrode layer 440c. That is, the gate 440 may include the gate insulating layer 440a, the ferroelectric layer 440b, and the gate electrode layer 440c that are sequentially stacked. The gate 440 may cover a part of the top surface of the channel region 430.

In some embodiments, the ferroelectric layer 440b may correspond to the first electrical element EE1 in FIG. 3.

In this case, the ferroelectric layer 440b may be formed by including at least one of PZT(Pb(Zr,Ti)O₃), SBT(SrBi₂Ta₂O₉), SBTN(SrBi₂(Ta,Nb)O₉), BLT((Bix,La1-x)₄Ti₃O₁₂), BST(BaxSr(1-x)TiO₃), hafnium oxide (Hf0O₂), silicon-added hafnium oxide (HfO₂/Si), aluminum-added hafnium oxide (HfO₂/Al), zirconium-added hafnium oxide (HfO₂/Zr), or a combination thereof.

The first electrode 450 may be disposed on a top surface of the first doped region 410. In an embodiment, the first electrode 450 may be a source electrode. The second electrode 460 may be disposed on a top surface of the second doped region 420. In an embodiment, the second electrode 460 may be a drain electrode.

In an embodiment, the FeTFET MT11 may be a tunnel field-effect transistor (TFET) using a band-to-band tunneling phenomenon. That is, the FeTFET MT11 may be a FeTFET including a ferroelectric layer. The FeTFET MT11 may have the first doped region 410 and the second doped region 420, which have opposite conductivity types, and a current flow of the FeTFET MT11 may be controlled by a bias applied to the gate 440.

The FeTFET MT11 may include a p-type source region (i.e., the first doped region 410), an n-type drain region (i.e., the second doped region 420), and the channel region 430 in an intrinsic state therebetween. Because the p-type Fermi level of a source region is different from the n-type Fermi level of a drain region while a bias is not applied to the source region, the drain region, and a gate (i.e., in a thermal equilibrium state), energy levels of a valence band and an electron band in the source region may be higher than those in the drain region. That is, the energy level of the source region may be higher than the energy level of the channel region, and the energy level of the drain region may be lower than the energy level of the channel region.

Because there is a wide potential barrier between the source region and the drain region when a reverse bias is applied between the source region and the drain region and a turn-off voltage (e.g., 0 V) is applied to the gate (i.e., in a turn-off state where no electric field is applied to the channel region), the tunneling of electric charges does not occur, and the flow of a current that is not smaller than a threshold current may not occur between the source region and the drain region. However, there may be a slight leakage current flow between the source region and the drain region.

Because a potential barrier between the channel region and the source region is narrowed when a reverse bias is applied between the source region and the drain region, and a gate voltage that is not lower than a threshold voltage is applied to the gate electrode (i.e., in a turn-on state where an electric field is applied to the channel region), a band-to-band tunneling phenomenon that electrons are quantum-mechanically tunneled from the valence band of the source region to the conduction band of the channel region may occur. Accordingly, a current flow may occur between the source region and the drain region.

The first FeTFET MT11 may control the flow of electrons or holes through the band-to-band tunneling, and thus a change in an output current may be great in spite of a slight change in a gate voltage level (or a driving voltage). That is, the FeTFET MT11 may have a small subthreshold swing. Accordingly, the FeTFET MT11 may be a semiconductor element capable of operating at a low voltage or low power.

In an embodiment, the semiconductor substrate 400, the first doped region 410, the second doped region 420, and the channel region 430 may be formed of a semiconductor material. For example, each of the semiconductor substrate 400, the first doped region 410, the second doped region 420, and the channel region 430 may be formed of at least one of a semiconductor material such as silicon, a semiconductor material (e.g., silicon-germanium (SiGe), germanium (Ge), indium gallium arsenide (InGaAs), or indium arsenide (InAs)) having a narrower bandgap, or a semiconductor material having a direct bandgap.

In an embodiment, all of the semiconductor substrate 400, the first doped region 410, the second doped region 420, and the channel region 430 may be formed of the same material. For example, all of the semiconductor substrate 400, the first doped region 410, the second doped region 420, and the channel region 430 may be formed of silicon. In an embodiment, the semiconductor substrate 400, the first doped region 410, the second doped region 420, and the channel region 430 may be formed of different materials from one another. For example, the semiconductor substrate 400, the second doped region 420, and the channel region 430 may be formed of silicon, and the first doped region 410 may be formed of silicon-germanium (SiGe).

Alternatively, the semiconductor substrate 400, the first doped region 410, and the channel region 430 may be formed of silicon, and the second doped region 420 may be formed of indium arsenide (InAs). Accordingly, the CAM device 1000 may facilitate the band-to-band tunneling of the FeTFET element MT11 and may reduce a turn-on voltage VTH, thereby improving a turn-on operation and a bipolar (ambipolar) operation.

FIGS. 10A and 10B are drawings for describing an operation of a first memory cell including a FeTFET. Referring to FIG. 10A, a method in which a bit value ‘1’ is programmed (or stored) in the FeTFET MT11 is described. Referring to FIG. 10B, a method in which a bit value ‘0’ is programmed (or stored) in the FeTFET MT11 is described. In FIGS. 10A and 10B, configurations having the same reference numerals as those in FIG. 9 correspond to each other.

As illustrated in FIG. 10A, in some embodiments, the ferroelectric layer 440b may have a first polarization state by applying a positive voltage to the gate electrode layer 440c and applying a ground voltage GND (alternatively, a specific voltage VSS equal to or lower than the ground voltage GND or a low voltage) to the first electrode 450 and the second electrode 460. For example, the first polarization state may be a down polarization state. Electrons may be accumulated in an upper portion of the channel region 430. A gate voltage may be applied to the gate electrode layer 440c, and thus ‘1’ may be programmed into the first memory cell.

As illustrated in FIG. 10B, in some embodiments, the ferroelectric layer 440b may have a second polarization state by applying a negative voltage to the gate electrode layer 440c and applying the ground voltage GND (or a specific voltage VSS equal to or lower than the ground voltage GND) to the first electrode 450 and the second electrode 460. For example, the second polarization state may be an up polarization state. Holes may be accumulated in the upper portion of the channel region 430. A gate voltage may be applied to the gate electrode layer 440c, and thus ‘0’ may be programmed into the first memory cell C11.

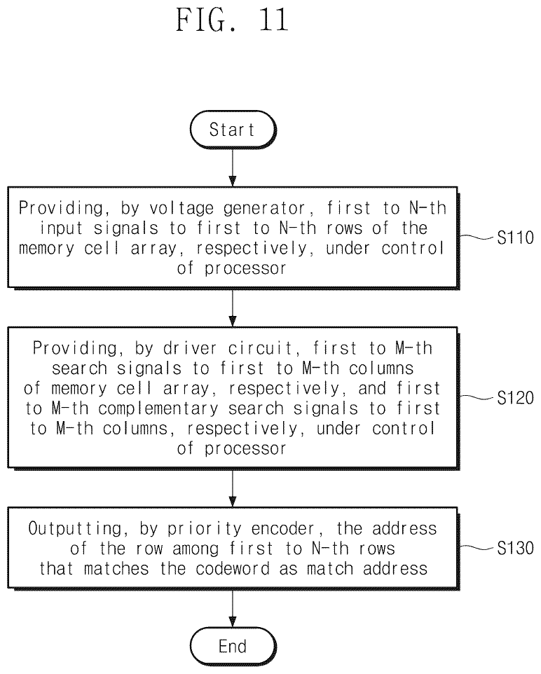

FIG. 11 is a drawing for describing an operating method of the CAM device of FIG. 1. Referring to FIG. 11, a CAM device may include a voltage generator, a driver circuit, a memory cell array, and a priority encoder. The CAM device may communicate with a processor.

In operation S110, the CAM device may provide first to N-th input signals to the first to N-th rows of the memory cell array through a voltage generator, respectively, under the control of a processor.

In operation S120, the CAM device may respectively provide first to M-th search signals to the first to M-th columns of the memory cell array and may provide respectively first to M-th complementary search signals to the first to M-th column, through a driver circuit under the control of the processor.

In operation S130, the CAM device may output an address of a row, which matches a codeword, from among the first to N-th rows as a match address through a priority encoder.

In some embodiments, operation S130 may include an operation of calculating first to N-th propagation delay times respectively corresponding to the first to N-th rows based on an operation of comparing between the first to N-th input signals and the first to N-th output signals respectively output from the first to N-th rows through the priority encoder, an operation of determining a row corresponding to the shortest propagation delay time among the first to N-th propagation delay times, and an operation of outputting an address of the determined row as the match address.

In this case, the memory cell array may include the first to N-th rows and the first to M-th columns. The first row may include first to M-th memory transistors respectively connected to the first to M-th columns. The first memory transistor among the first to M-th memory transistors includes a first source terminal for receiving the first complementary search signal, a first gate terminal for receiving the first input signal, a first drain terminal for receiving the first search signal, and a first electrical element. When the first code of a codeword corresponding to the first search signal and the first complementary search signal corresponds to the programmed state of the first electrical element, a capacitance value of the first memory transistor is smaller than a threshold value.

In some embodiments, each of the first to M-th memory transistors may be a FeTFET.

The above description refers to embodiments for implementing the present disclosure. Embodiments in which a design is changed simply or which are easily changed may be included in the present disclosure as well as an embodiment described above. In addition, technologies that are easily changed and implemented by using the above embodiments may be included in the present disclosure. While the present disclosure has been described with reference to embodiments described above, it will be apparent to those of ordinary skill in the art that various changes and modifications may be made thereto without departing from the spirit and scope of the present disclosure as set forth in the following claims.

According to an embodiment of the present disclosure, a CAM device and an operating method thereof are provided.

Furthermore, one memory cell of a CAM device may be implemented with only one transistor, and a CAM operation may be simplified to a linear operation by using a transistor's characteristic having low capacitance only at a specific gate voltage, thereby providing high-capacity, high-integration, miniaturization, and low-power CAM devices.

While the present disclosure has been described with reference to embodiments thereof, it will be apparent to those of ordinary skill in the art that various changes and modifications may be made thereto without departing from the spirit and scope of the present disclosure as set forth in the following claims.

What is claimed is:

1. A content addressable memory (CAM) device communicating with a processor, the CAM device comprising:
a memory cell array including first to N-th rows and first to M-th columns;
a voltage generator configured to respectively provide first to N-th input signals to the first to N-th rows under control of the processor;
a driver circuit configured to respectively provide first to M-th search signals to the first to M-th columns and to respectively provide first to M-th complementary search signals to the first to M-th columns under control of the processor; and
a priority encoder connected to the first to N-th rows,
wherein a first row among the first to N-th rows includes first to M-th memory transistors respectively connected to the first to M-th columns,
wherein the first memory transistor among the first to M-th memory transistors includes a first source terminal configured to receive the first complementary search signal, a first gate terminal configured to receive the first input signal, a first drain terminal configured to receive the first search signal, and
a first electrical element,
wherein when a first code of a codeword corresponding to the first search signal and the first complementary search signal corresponds to a programmed state of the first electrical element, a capacitance value of the first memory transistor is smaller than a threshold value, and
wherein each of the ‘N’ and the ‘M’ is an arbitrary natural number.

2. The CAM device of claim 1, wherein the codeword include first to M-th codes, and
wherein the driver circuit is configured to:
generate the first to M-th search signals and the first to M-th complementary search signals, which correspond to the first to M-th codes, respectively.

3. The CAM device of claim 2, wherein the programmed state of the first electrical element indicates one of a first bit value and a second bit value,
wherein when the first code corresponds to the first bit value, the capacitance value of the first memory transistor is a first capacitance value smaller than the threshold value, and
wherein when the first code corresponds to the second bit value, the capacitance value of the first memory transistor is a second capacitance value greater than the threshold value.

4. The CAM device of claim 1, wherein in the first memory transistor, the capacitance value of the first memory transistor is smaller than or equal to the threshold value when a gate voltage level of the gate terminal is higher than or equal to a first voltage level and smaller than or equal to a second voltage level, and the capacitance value is greater than the threshold value otherwise.

5. The CAM device of claim 4, wherein the gate voltage level is determined based on the first input signal, the first search signal, and the first complementary search signal.

6. The CAM device of claim 1, wherein the programmed state indicates one of a first bit value and a second bit value,
wherein in the first memory transistor of which the programmed state indicates the first bit value, the capacitance value of the first memory transistor is smaller than the threshold value when a gate voltage level of the gate terminal is higher than or equal to a first voltage level and lower than or equal to a second voltage level, and the capacitance value is greater than or equal to the threshold value otherwise,
wherein in the first memory transistor of which the programmed state indicates the second bit value, the capacitance value of the first memory transistor is smaller than the threshold value when the gate voltage level of the gate terminal is higher than or equal to a third voltage level and lower than or equal to a fourth voltage level, and the capacitance value is greater than or equal to the threshold value otherwise, and
wherein the third voltage level is higher than the first voltage level, and the fourth voltage level is higher than the second voltage level.

7. The CAM device of claim 1, wherein each of the first to M-th columns is connected to one search line, which receives a corresponding search signal among the first to M-th search signals, and one complementary search line, which receives a corresponding complementary search signal among the first to M-th complementary search signals.

8. The CAM device of claim 1, wherein the capacitance value is a first capacitance value,
wherein the programmed state is a first programmed state,
wherein the threshold value is a first threshold value,
wherein the second memory transistor among the first to M-th memory transistors includes a second source terminal configured to receive the second complementary search signal, a second gate terminal configured to receive the first input signal, a second drain terminal configured to receive the second search signal, and a second electrical element, and
wherein when the second code among the first to M-th codes of the codeword corresponding to the second search signal and the second complementary search signal corresponds to a second programmed state of the second electrical element, a second capacitance value of the second memory transistor is smaller than the threshold value.

9. The CAM device of claim 1, wherein the priority encoder is further configured to:
calculate first to N-th propagation delay times respectively corresponding to the first to N-th rows based on an operation of comparing between the first to N-th input signals and first to N-th output signals output from the first to N-th rows.

10. The CAM device of claim 9, wherein the priority encoder is further configured to:
output an address of a row corresponding to a shortest propagation delay time among the first to N-th propagation delay times as a match address.

11. The CAM device of claim 9, wherein as the number of mismatch bits between bits stored by the first to M-th memory transistors and the codeword is great, the first propagation delay time among the first to N-th propagation delay times increases linearly.

12. The CAM device of claim 10, wherein the priority encoder is configured to:
determine the number of mismatch bits between the codeword and stored bits for each of the first to N-th rows based on the first to N-th propagation delay times.

13. The CAM device of claim 1, wherein each of the first to M-th memory transistors is a ferroelectric tunnel field-effect transistor (FeTFET).

14. The CAM device of claim 13, wherein the FeTFET includes:
a first doped region having a first conductivity type;
a second doped region having a second conductivity type different from the first conductivity type;
a channel region formed between the first doped region and the second doped region; and
a gate formed on the channel region,
wherein the gate includes a gate insulating layer, a ferroelectric layer, and a gate electrode layer, and
wherein the ferroelectric layer includes at least one of PZT(Pb(Zr,Ti)O₃), SBT(SrBi₂Ta₂O₉), SBTN(SrBi₂(Ta,Nb)O₉), BLT((Bix,La1-x)₄Ti₃O₁₂), BST(BaxSr(1-x)TiO₃), hafnium oxide (HfO₂), silicon-added hafnium oxide (HfO₂/Si), aluminum-added hafnium oxide (HfO₂/Al), or zirconium-added hafnium oxide (HfO₂/Zr).

15. The CAM device of claim 14, wherein the first electrical element indicates the ferroelectric layer, and
wherein the first memory transistor stores one of a first bit value and a second bit value depending on a polarization state of the ferroelectric layer.

16. The CAM device of claim 1, further comprising:
first to N-th input inverter circuits respectively connected between the voltage generator and the first to N-th rows.

17. The CAM device of claim 1, further comprising:
first to N-th output inverter circuits respectively connected between the priority encoder and the first to N-th rows.

18. The CAM device of claim 1, further comprising:
first to fourth time-to-digital convertor (TDC) circuits respectively connected between the priority encoder and the first to N-th rows.

19. The CAM device of claim 1, further comprising:
first to N-th resistance component respectively connected between the voltage generator and the first to N-th rows.

20. An operating method of a CAM device communicating with a processor, the method comprising:
providing, by a voltage generator, first to N-th input signals to first to N-th rows of a memory cell array under control of the processor, respectively; and
providing, by a driver circuit, first to M-th search signals to first to M-th columns of the memory cell array, respectively, and providing first to M-th complementary search signals to the first to M-th column, respectively, under control of the processor,
wherein a first row among the first to N-th rows includes first to M-th memory transistors respectively connected to the first to M-th columns,
wherein the first memory transistor among the first to M-th memory transistors includes a first source terminal configured to receive the first complementary search signal, a first gate terminal configured to receive the first input signal, a first drain terminal configured to receive the first search signal, and
a first electrical element,
wherein when a first code of a codeword corresponding to the first search signal and the first complementary search signal corresponds to a programmed state of the first electrical element, a capacitance value of the first memory transistor is smaller than a threshold value, and
wherein each of the ‘N’ and the ‘M’ is an arbitrary natural number.

21. The method of claim 20, further comprising:
outputting, by a priority encoder, an address of a row, which matches the codeword, from among the first to N-th rows as a match address.

22. The method of claim 21, wherein the outputting, by the priority encoder, of the address of the row, which matches the codeword, from among the first to N-th rows as the match address includes:
calculating first to N-th propagation delay times respectively corresponding to the first to N-th rows based on an operation of comparing between the first to N-th input signals and the first to N-th output signals output from the first to N-th rows;
determining a row corresponding to a shortest propagation delay time among the first to N-th propagation delay times; and
outputting an address of the determined row as the match address.

23. The method of claim 20, wherein each of the first to M-th memory transistors is a FeTFET.

24. A CAM system comprising:
a CAM device; and
a processor configured to control the CAM device,
wherein the CAM device includes:
a memory cell array including first to N-th rows and first to M-th columns;
a voltage generator configured to respectively provide first to N-th input signals to the first to N-th rows under control of the processor;
a driver circuit configured to respectively provide first to M-th search signals to the first to M-th columns and to respectively provide first to M-th complementary search signals to the first to M-th columns under control of the processor; and
a priority encoder connected to the first to N-th rows,
wherein a first row among the first to N-th rows includes first to M-th memory transistors respectively connected to the first to M-th columns,
wherein the first memory transistor among the first to M-th memory transistors includes a first source terminal configured to receive the first complementary search signal, a first gate terminal configured to receive the first input signal, a first drain terminal configured to receive the first search signal, and
a first electrical element,
wherein when a first code of a codeword corresponding to the first search signal and the first complementary search signal corresponds to a programmed state of the first electrical element, a capacitance value of the first memory transistor is smaller than a threshold value, and
wherein each of the ‘N’ and the ‘M’ is an arbitrary natural number.
